(19) United States
(12) Patent Application Publication
(10) Pub. No.: US 2022/0397352 A1
(43) Pub. Date: Dec. 15, 2022

(54) GRAPHITE COMPOSITE LAMINATED HEAT-DISSIPATING STRUCTURE AND MANUFACTURING METHOD THEREOF

(71) Applicant: LONG YOUNG (SAMOA) HOLDING CO., LIMITED, TAIWAN BRANCH (SAMOA), NEW TAIPEI CITY (TW)

(72) Inventors: KUO-CHEN HSU, Hsinchu County (TW); CHIA-YANG KUO, Hsinchu County (TW); CHIEN-HAO SU, Hsinchu County (TW); CHAO-TE LIN, Hsinchu County (TW)

(21) Appl. No.: 17/840,302

(22) Filed: Jun. 14, 2022

(30) Foreign Application Priority Data
Jun. 15, 2021 (TW) 110121696

(51) Int. Cl. F28F 21/02; F28F 21/08; C23C 14/06

(52) U.S. Cl. CPC F28F 21/02; F28F 21/085; C23C 14/0605; F28F 2245/00

(57) ABSTRACT

graphite composite laminated heat-dissipating structure and a manufacturing method thereof are disclosed. The structure includes a metal substrate and a graphite heat-dissipating layer. The metal substrate has a first surface having a roughness ranging between 0.01 and 10 μm. The graphite heat-dissipating layer is composed of pure graphite and is directly formed on the first surface by means of physical vapor deposition using a carbon sputtering target. The graphite heat-dissipating layer has a thickness ranging between 0.05 and 2 μm. The manufacturing method includes S1: directly forming a graphite heat-dissipating layer on a first surface of a metal substrate by means of physical vapor deposition using a carbon sputtering target after the metal substrate has received plasma treatment or infrared heating; and S2: stopping the physical vapor deposition when the graphite heat-dissipating layer has a thickness ranging between 0.05 and 2 μm.

### BACKGROUND OF THE INVENTION

### 1. Technical Field

The present invention relates to a heat-dissipating structure, and more particularly to a graphite composite laminated heat-dissipating structure and a manufacturing method thereof.

### 2. DESCRIPTION OF RELATED ART

It is known that a motherboard in a computer device carries various electronic chips. When the computer device operates, these electronic chips can generate considerable heat. The heat has to be conducted away from the electronic chips or the computer device can break due to high heat. In the context, heat-dissipating efficiency are becoming increasingly important as chips run faster and faster and can become a factor that limits performance of computer devices.

Conventionally, artificial graphite is used in the industry as a solution for heat dissipation, but the minimum possible thickness of artificial graphite is as high as 25 μm, making the low vertical heat conductivity (<16 W/mK) of an artificial graphite layer a problem. Besides, artificial graphite tends to splinter during processing.

Another existing solution is to apply a graphene-resin mixture on to copper foil or aluminum foil to form a heat-conducting layer. However, the bond of resin and metal foil is usually weak and consequently the resin tends to come off from the metal foil. In addition, with the presence of the resin, the thickness of the resulting structure is significantly increased and in turn the overall heat conductivity can be significantly decreased, which is adverse to applications of the product in which the heat conductivity is particularly low in the vertical direction.

### SUMMARY OF THE INVENTION

In order to address the foregoing issues, the present invention discloses a graphite composite laminated heat-dissipating structure, which has a graphite heat-dissipating layer formed on the metal substrate surface, wherein the graphite heat-dissipating layer features continuous and even formation, and the graphite heat-dissipating layer thickness is thin, which means that the vertical distance is short, so that heat can be transmitted to the metal substrate rapidly, thereby making the disclosed structure feature high transverse heat transmission capacity and high vertical heat transmission capacity.

In one embodiment, the present invention provides a graphite composite laminated heat-dissipating structure, which comprises a metal substrate and a graphite heat-dissipating layer. The metal substrate has a first surface having surface roughness (Ra) ranging between 0.01 and 10 μm. The graphite heat-dissipating layer is composed of pure graphite. The graphite heat-dissipating layer is directly formed on the first surface by means of physical vapor deposition using a carbon sputtering target. The graphite heat-dissipating layer has a thickness ranging between 0.05 and 2 μm.

In another embodiment, the present invention provides a manufacturing method of a graphite composite laminated heat-dissipating structure, which comprises the following steps: S1: directly forming a graphite heat-dissipating layer on a first surface of a metal substrate by means of physical vapor deposition using a carbon sputtering target, wherein the first surface has surface roughness (Ra) ranging between 0.01 and 10 μm, and S2: stopping the physical vapor deposition when the graphite heat-dissipating layer has a thickness ranging between 0.05 and 2 μm.

Thereby, the graphite heat-dissipating layer is formed on the surface of the metal substrate and features continuous and even formation, and since the graphite heat-dissipating layer is thin, which means that the vertical distance is short, heat can be transmitted to the metal substrate rapidly, thereby making the present invention features high transverse heat transmission capacity and high vertical heat transmission capacity.

Additionally, in the present invention, the metal substrate may have received plasma treatment or infrared heating to enhance the surface of the metal substrate in terms of ionic, bonding capacity. Besides, since the graphite heat-dissipating layer is deposited on the first surface by means of ion bombardment using the carbon sputtering target, it is formed on the first surface with improved firmness.

### BRIEF DESCRIPTION OF THE DRAWINGS

FIG. 1 is a schematic drawing of a graphite composite laminated heat-dissipating structure according to one embodiment of the present invention.

FIG. 2 is a schematic drawing of the graphite composite laminated heat-dissipating structure according to another embodiment of the present invention.

FIG. 3 is an applied view of the graphite composite laminated heat-dissipating structure according to the embodiment of the present invention, showing the structure mounted between a circuit board and a case.

FIG. 4 is a flowchart of a manufacturing method of the graphite composite laminated heat-dissipating structure according to the present invention embodiment.

### DETAILED DESCRIPTION OF THE INVENTION

The following preferred embodiments when read with the accompanying drawings are made to clearly exhibit the above-mentioned and other technical contents, features and effects of the present invention. Through the exposition by means of the specific embodiments, people would further understand the technical means and effects the present invention adopts to achieve the above-indicated objectives. However, the accompanying drawings are intended for reference and illustration, but not to limit the present invention and are not made to scale.

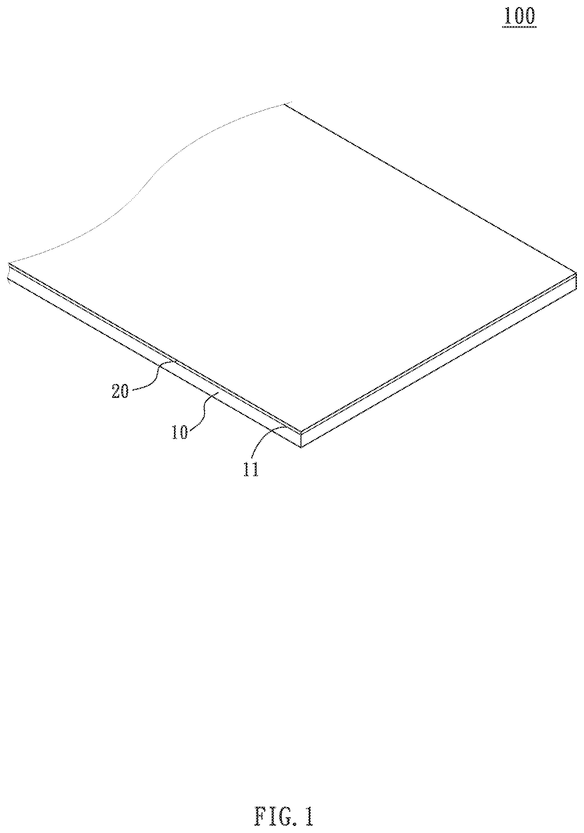

Referring to FIG. 1 through FIG. 3, a graphite composite laminated heat-dissipating structure 100 in one embodiment of the present invention comprises a metal substrate 10 and a graphite heat-dissipating layer 20.

The metal substrate 10 has a first surface 11, which has surface roughness (Ra) ranging between 0.01 and 10 μm. As shown in FIG. 1, in the present embodiment, the metal substrate 10 is made of copper and has a thickness ranging between 1 and 250 μm, so that the thickness of the metal substrate 10 is greater than the thickness of the graphite heat-dissipating layer 20. The metal substrate 10 may have received plasma treatment or infrared heating to enhance the first surface 11 in terms of ionic bonding capacity.

The graphite heat-dissipating layer 20 is based on a carbon sputtering target. The graphite heat-dissipating layer 20 is formed on the first surface 11. The graphite heat-dissipating layer 20 has a thickness ranging between 0.05 and 2 μm. As shown in FIG. 1, in the present embodiment, the graphite heat-dissipating layer 20 has a transverse thermal conductivity ranging between 800 and 1800 W/m·K. The graphite heat-dissipating layer 20 is directly formed on the first surface 11 by means of physical vapor deposition using the carbon sputtering target.

Therein, the graphite heat-dissipating layer 20 is continuously and evenly deposited on the first surface 11 such that the graphite heat-dissipating layer 20 has high transverse heat transmission capacity. Moreover, since the graphite heat-dissipating layer 20 is thin, which means that the vertical distance is short, so it can transmit heat to the metal substrate 10 in the vertical direction rapidly, making the present invention feature high vertical heat transmission capacity as well.

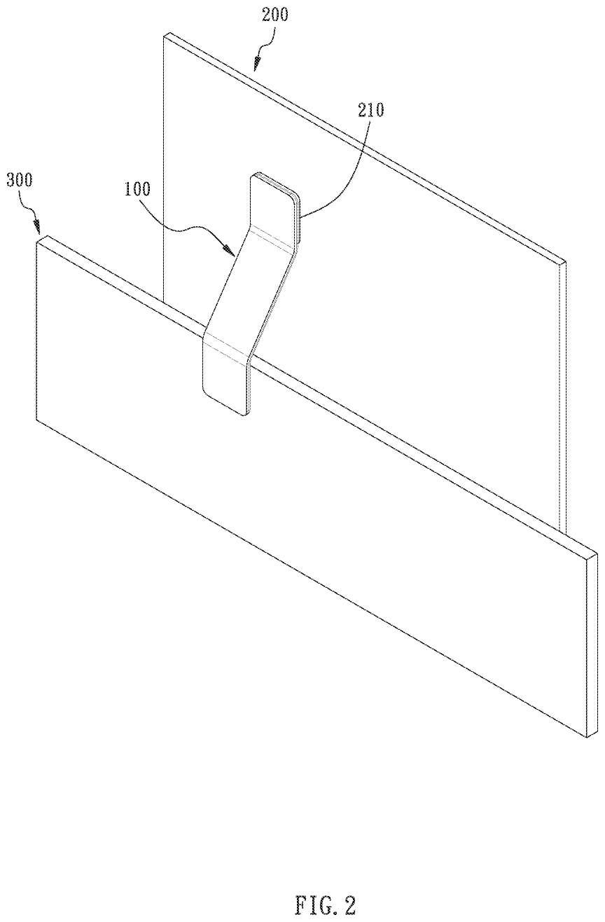

As shown in FIG. 2, in addition to FIG. 1, one end of the graphite composite laminated heat-dissipating structure 100 of the present invention is mounted on an element 210 of a circuit board 200, and the opposite end is mounted on a case 300. When the element 210, as a heat source, generates heat, the disclosed structure 100, in virtue of the high heat transmission capacity of the graphite heat-dissipating layer 20, can rapidly conduct the heat transversely away from the element 210 and transmit the heat to the case 300. In this way, heat can be rapidly transmitted from the heat source to the surface and dissipated, thereby achieving rapid heat dissipation. Besides, since the graphite heat-dissipating layer 20 has its thickness ranging between 0.05 and 2 μm, the graphite heat-dissipating layer 20 is dark at its surface, showing a blackish non-transparent appearance, which contributes to better heat radiation absorption.

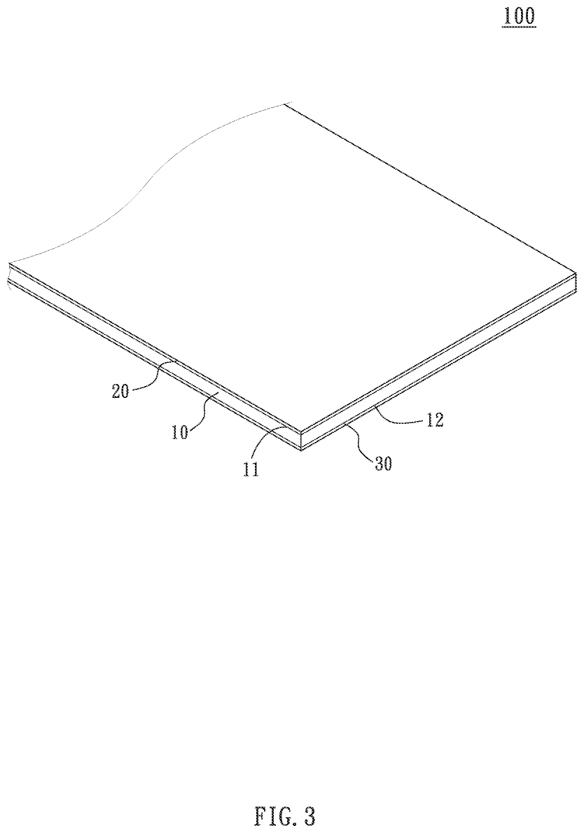

As shown in FIG. 3, in another embodiment of the present invention, the metal substrate 10 further comprises a second surface 12 opposite to the first surface 11, and an additional graphite heat-dissipating layer 30 is formed on the second surface 12. The additional graphite heat-dissipating layer 30 is also formed by means of physical vapor deposition using a carbon sputtering target, so that heat at the second surface 12 can be rapidly transmitted outward through the additional graphite heat-dissipating layer 30 by means of transverse conduction, so as to enhance the heat-dissipating effect of the disclosed structure 100.

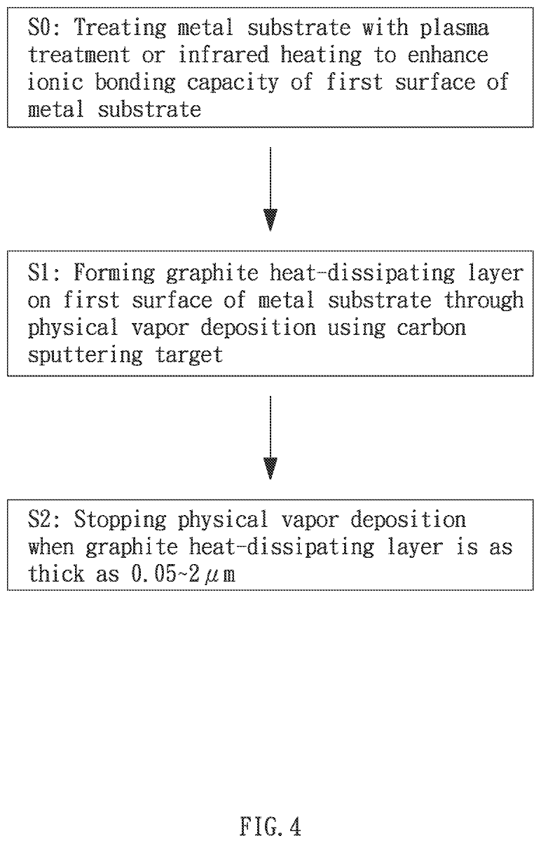

In order to produce the graphite composite laminated heat-dissipating structure 100 as described previously, the present invention further provides a manufacturing method comprising the steps detailed below and shown in FIG. 1 and FIG. 4.

In the step S1, a carbon sputtering target is deposited on a first surface 11 of a metal substrate 10 by means of physical vapor deposition to form a graphite heat-dissipating layer 20. The first surface 11 has surface roughness (Ra) ranging between 0.01 and 10 μm. In the present embodiment, the metal substrate 10 is made of copper. The metal substrate 10 has a thickness ranging between 1 and 250 μm, and the thickness of the metal substrate 10 is greater than the thickness of the graphite heat-dissipating layer 20. In the present embodiment, physical vapor deposition despites pure graphite on the first surface 11 by means of ion bombardment using the carbon sputtering target to form the graphite heat-dissipating layer 20.

Step S2 is about stopping the physical vapor deposition when the graphite heat-dissipating layer 20 has a thickness ranging between 0.05 and 2 μm. In the present embodiment, the graphite heat-dissipating layer 20 has a thickness smaller than the thickness of the metal substrate 10.

Further, in the present embodiment, before step S1, there is a step S0 of treating the metal substrate 10 with plasma treatment or infrared heating to enhance the first surface 11 of the metal substrate 10 in terms of ionic bonding capacity. This makes the carbon sputtering target form the graphite heat-dissipating layer 20 on first surface 11 with improved firmness.

Further, in the step S1, the metal substrate 10 may be supplied in a roll form and conveyed in a conveying direction (not shown in the drawings), while the carbon sputtering target is deposited on the first surface 11 by means of physical vapor deposition continuously to form the graphite heat-dissipating layer 20. After the step S2, the manufactured graphite composite laminated heat-dissipating structure 100 is rolled up into a roll.

With the features described previously, the present invention provides the following advantages:

1. In the present invention, the graphite heat-dissipating layer 20 is continuously and evenly deposited on the first surface 11 by means of physical vapor deposition, so the graphite heat-dissipating layer 20 has high transverse heat transmission capacity.

2. In the present invention, since the graphite heat-dissipating layer 20 has its thickness as thin as 0.05 to 2 μm, and thus the vertical distance from it to the metal substrate 10 is short, heat can be transmitted vertically to the metal substrate 10 rapidly, making the present invention feature high vertical heat transmission capacity.

3. In the present invention, the graphite heat-dissipating layer 20 has its thickness ranging between 0.05 and 2 μm, so it has a dark, non-transparent appearance, which contributes to better heat radiation absorption.

4. In the present invention, the metal substrate 10 may be treated using plasma treatment or infrared heating to enhance the first surface 11 in terms of ionic bonding capacity, and since the graphite heat-dissipating layer 20 is formed by depositing pure graphite on the first surface 11 by means of ion bombardment using the carbon sputtering target, the graphite heat-dissipating layer 20 can be formed on the first surface 11 with improved firmness.

5. In the present invention, the metal substrate is supplied in a roll form and conveyed in a conveying direction (not shown in the drawings), so that the carbon sputtering target can be continuously deposited on the first surface 11, thereby achieving continuous manufacturing and allowing the product to have an arbitrary length.

6. In the present invention, the metal substrate is made of copper, which is resident to electromagnetic interference, so that the disclosed structure 100 installed in a computer device will not interfere with operation of electronic elements in the computer device.

The present invention has been described with reference to the preferred embodiments and it is understood that the embodiments are not intended to limit the scope of the present invention. Moreover, as the contents disclosed herein should be readily understood and can be implemented by a person skilled in the art, all equivalent changes or modifications which do not depart from the concept of the present invention should be encompassed by the appended claims.

What is claimed is:

1. A graphite composite laminated heat-dissipating structure, comprising:
a metal substrate, having a first surface that has surface roughness (Ra) ranging between 0.01 and 10 μm; and
a graphite heat-dissipating layer, being composed of pure graphite and directly formed on the first surface by means of physical vapor deposition using a carbon sputtering target, wherein the graphite heat-dissipating layer has a thickness ranging between 0.05 and 2 μm.

2. The graphite composite laminated heat-dissipating structure of claim 1, wherein the graphite heat-dissipating layer has a transverse thermal conductivity ranging between 800 and 1800 W/m·K.

3. The graphite composite laminated heat-dissipating structure of claim 1, wherein the metal substrate has a thickness ranging between 1 and 250 μm, and the thickness of the metal substrate is greater than the thickness of the graphite heat-dissipating layer.

4. The graphite composite aminated heat-dissipating structure of claim 1, wherein the metal substrate is made of copper.

5. The graphite composite laminated heat-dissipating structure of claim 1, wherein the metal substrate further comprises a second surface disposed oppositely to the first surface and an additional graphite heat-dissipating layer is formed on the second surface.

6. A manufacturing method of a graphite composite laminated heat-dissipating structure, the method comprising steps of:
S1: directly forming a graphite heat-dissipating layer on a first surface of a metal substrate by means of physical vapor deposition using a carbon sputtering target after the metal substrate has received plasma treatment or infrared heating, wherein the first surface has surface roughness (Ra) ranging between 0.01 and 10 μm; and
S2: stopping the physical vapor deposition when the graphite heat-dissipating layer has a thickness ranging between 0.05 and 2 μm.

7. The manufacturing method of claim 6, wherein the metal substrate is made of copper.

8. The manufacturing method of claim 6, wherein the physical vapor deposition deposits pure graphite on the first surface of the metal substrate by means of ion bombardment using the carbon sputtering target, so as to form the graphite heat-dissipating layer.

9. The manufacturing method of claim 6, wherein in the step S1, the metal substrate is supplied in a roll form and conveyed in a conveying direction so that while the carbon sputtering target is deposited on the first surface by means of physical vapor deposition to form the graphite heat-dissipating layer.
